(19) United States
(12) Patent Application Publication
(10) Pub. No.: US 2024/0223154 A1
(43) Pub. Date: Jul. 4, 2024

(54) ACOUSTIC WAVE DEVICE

(71) Applicant: Murata Manufacturing Co., Ltd., Nagaokakyo-shi (JP)

(72) Inventor: Naoki OSHIMA, Nagaokakyo-shi (JP)

(21) Appl. No.: 18/390,436

(22) Filed: Dec. 20, 2023

(30) Foreign Application Priority Data
Dec. 28, 2022 (JP) 2022-212650

(51) Int. Cl. H03H 9/02; H03H 9/145; H03H 9/25

(52) U.S. Cl. CPC H03H 9/02818; H03H 9/02574; H03H 9/02637; H03H 9/02889; H03H 9/02992; H03H 9/145; H03H 9/25

(57) ABSTRACT

In an acoustic wave device, a resonator including an IDT electrode and a portion of a piezoelectric substrate includes a middle region, a first gap region, a second gap region, a first edge region, a second edge region, a first intermediate region, and a second intermediate region. The first intermediate region is located between the middle region and the first edge region. The second intermediate region is located between the middle region and the second edge region. An acoustic wave velocity in the first intermediate region and in the second intermediate region are lower than an acoustic wave velocity in the middle region and higher than an acoustic wave velocity in the first edge region and an acoustic wave velocity in the second edge region.

### CROSS REFERENCE TO RELATED APPLICATIONS

This application claims the benefit of priority to Japanese Patent Application No. 2022-212650 filed on Dec. 28, 2022. The entire contents of this application are hereby incorporated herein by reference.

### BACKGROUND OF THE INVENTION

### 1. Field of the Invention

The present invention relates to an acoustic wave device and, more particularly, to an acoustic wave device including an IDT electrode.

### 2. Description of the Related Art

Japanese Unexamined Patent Application Publication No. 2018-174595 discloses an acoustic wave device including a piezoelectric film and an IDT electrode provided on the piezoelectric film.

In the acoustic wave device disclosed in Japanese Unexamined Patent Application Publication No. 2018-174595, the IDT electrode includes a first busbar, a second busbar spaced apart from the first busbar, a plurality of first electrode fingers that have base ends electrically connected to the first busbar and have front ends extending toward the second busbar, and a plurality of second electrode fingers that have base ends connected to the second busbar and have front ends extending toward the first busbar.

Each of the first busbar and the second busbar has an opening portion, an inner busbar portion, and an outer busbar portion.

In the acoustic wave device disclosed in FIG. 9 in Japanese Unexamined Patent Application Publication No. 2018-174595, one wide portion is provided at the front end of each of the second electrode fingers. None of the first electrode fingers have a wide portion in the vicinity of the wide portion of the second electrode finger. In addition, in this acoustic wave device, one wide portion is provided at the front end of the first electrode finger. The second electrode finger has no wide portion in the vicinity of the wide portion of the first electrode finger.

### SUMMARY OF THE INVENTION

In the acoustic wave device in which the wide portions are provided at the front ends of the electrode fingers of the IDT electrode, it may be necessary to further suppress the ripple of an unwanted wave that occurs in the resonance characteristics of a resonator including the IDT electrode.

Example embodiments of the present invention provide acoustic wave devices that each further suppress ripples of unwanted waves occurring in resonance characteristics of resonators including IDT electrodes.

An acoustic wave device according to an aspect of an example embodiment of t the present invention includes a piezoelectric substrate, and an IDT electrode on the piezoelectric substrate, in which the IDT electrode includes a first busbar, a second busbar that faces the first busbar in a first direction, a plurality of first electrode fingers that are connected to the first busbar and extend from the first busbar toward the second busbar in the first direction, and a plurality of second electrode fingers that are connected to the second busbar and extend from the second busbar toward the first busbar in the first direction, in the IDT electrode, the plurality of first electrode fingers and the plurality of second electrode fingers are spaced apart from each other in a second direction intersecting the first direction, each of the first busbar and the second busbar includes an opening portion, an inner busbar portion located closer than the opening portion to the plurality of first electrode fingers and the plurality of second electrode fingers in the first direction, an outer busbar portion located opposite to the inner busbar portion across the opening portion in the first direction, and a coupling portion that couples the inner busbar portion and the outer busbar portion to each other in the first direction, when a region between an envelope of front edges of the plurality of first electrode fingers and an envelope of front edges of the plurality of second electrode fingers is an intersection region, a resonator including the IDT electrode and a portion of the piezoelectric substrate includes a plurality of regions that differ from each other in the first direction in plan view in a thickness direction of the piezoelectric substrate, and the plurality of regions include a middle region that includes a middle portion in the first direction of the intersection region of the IDT electrode, middle portions in the first direction of the plurality of first electrode fingers, and middle portions in the first direction of the plurality of second electrode fingers, a first gap region including gaps between the first busbar and the plurality of second electrode fingers, a second gap region including gaps between the second busbar and the plurality of first electrode fingers, a first edge region including front-end portions of the plurality of second electrode fingers, a second edge region including front-end portions of the plurality of first electrode fingers, a first intermediate region located between the middle region and the first edge region, and a second intermediate region located between the middle region and the second edge region, an acoustic wave velocity in the first gap region and an acoustic wave velocity in the second gap region are higher than an acoustic wave velocity in the middle region, and an acoustic wave velocity in the first intermediate region and an acoustic wave velocity in the second intermediate region are lower than the acoustic wave velocity in the middle region and higher than an acoustic wave velocity in the first edge region and an acoustic wave velocity in the second edge region.

An acoustic wave device according to an aspect of another example embodiment of the present invention includes a piezoelectric substrate, and an IDT electrode on the piezoelectric substrate, in which the IDT electrode includes a first busbar, a second busbar that faces the first busbar in a first direction, a plurality of first electrode fingers that are connected to the first busbar and extend from the first busbar toward the second busbar in the first direction, and a plurality of second electrode fingers that are connected to the second busbar and extend from the second busbar toward the first busbar in the first direction, in the IDT electrode, the plurality of first electrode fingers and the plurality of second electrode fingers are spaced apart from each other in a second direction intersecting the first direction, each of the first busbar and the second busbar includes an opening portion, an inner busbar portion located closer than the opening portion to the plurality of first electrode fingers and the plurality of second electrode fingers in the first direction, an outer busbar portion located opposite to the inner busbar portion across the opening portion in the first direction, and a coupling portion that couples the inner busbar portion and the outer busbar portion to each other in the first direction, when a region between an envelope of front edges of the plurality of first electrode fingers and an envelope of front edges of the plurality of second electrode fingers is an intersection region, a resonator including the IDT electrode and a portion of the piezoelectric substrate includes a plurality of regions that differ from each other in the first direction in plan view in a thickness direction of the piezoelectric substrate, and the plurality of regions include a middle region that includes a middle portion in the first direction of the intersection region of the IDT electrode, middle portions in the first direction of the plurality of first electrode fingers, and middle portions in the first direction of the plurality of second electrode fingers, a first gap region including gaps between the first busbar and the plurality of second electrode fingers, a second gap region including gaps between the second busbar and the plurality of first electrode fingers, a first edge region including front-end portions of the plurality of second electrode fingers, a second edge region including front-end portions of the plurality of first electrode fingers, a first intermediate region located between the middle region and the first edge region, and a second intermediate region located between the middle region and the second edge region, at least one second electrode finger of the plurality of second electrode fingers has a first thickness and a first width in the middle region, has the first thickness and a second width in the first edge region, and has a second thickness and the first width in the first intermediate region, at least one first electrode finger of the plurality of first electrode fingers has the first thickness and the first width in the middle region, has the second thickness and the first width in the second edge region, and has the second thickness and the first width in the second intermediate region, and the second thickness is greater than the first thickness, and the second width is greater than the first width.

The acoustic wave devices according to example embodiments of the present invention each further suppress ripples of unwanted waves.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of a portion of an acoustic wave device according to a first example embodiment of the present invention.

FIG. 2 is a sectional view of the acoustic wave device taken along line X1-X1 in FIG. 1.

FIG. 3 is a sectional view of the acoustic wave device taken along line X2-X2 in FIG. 1.

FIG. 4 is a sectional view of the acoustic wave device taken along line Y1-Y1 in FIG. 1.

FIG. 5 is a sectional view of the acoustic wave device taken along line Y2-Y2 in FIG. 1.

FIG. 6 is a diagram for describing the dimensions of the acoustic wave device.

FIG. 7 is an explanatory diagram for schematically illustrating the velocity distribution of the acoustic velocity in a first direction of an acoustic wave that propagates in an acoustic wave propagation direction (second direction) in the acoustic wave device.

FIG. 8A is a perspective view of a first electrode finger of an IDT electrode of the acoustic wave device.

FIG. 8B is a perspective view of a second electrode finger of the IDT electrode of the acoustic wave device.

FIG. 9 is a diagram illustrating impedance-frequency characteristics of a resonator of the acoustic wave device.

FIG. 10 is a diagram illustrating impedance-frequency characteristics of a resonator of an acoustic wave device according to a comparative example.

FIG. 11 is an explanatory diagram for schematically illustrating the velocity distribution of the acoustic velocity in the first direction of an acoustic wave that propagates in the acoustic wave propagation direction (second direction) in an acoustic wave device according to a second example embodiment of the present invention.

FIG. 12 is a sectional view of a portion of an acoustic wave device according to a third example embodiment of the present invention.

### DETAILED DESCRIPTION OF THE EXAMPLE EMBODIMENTS

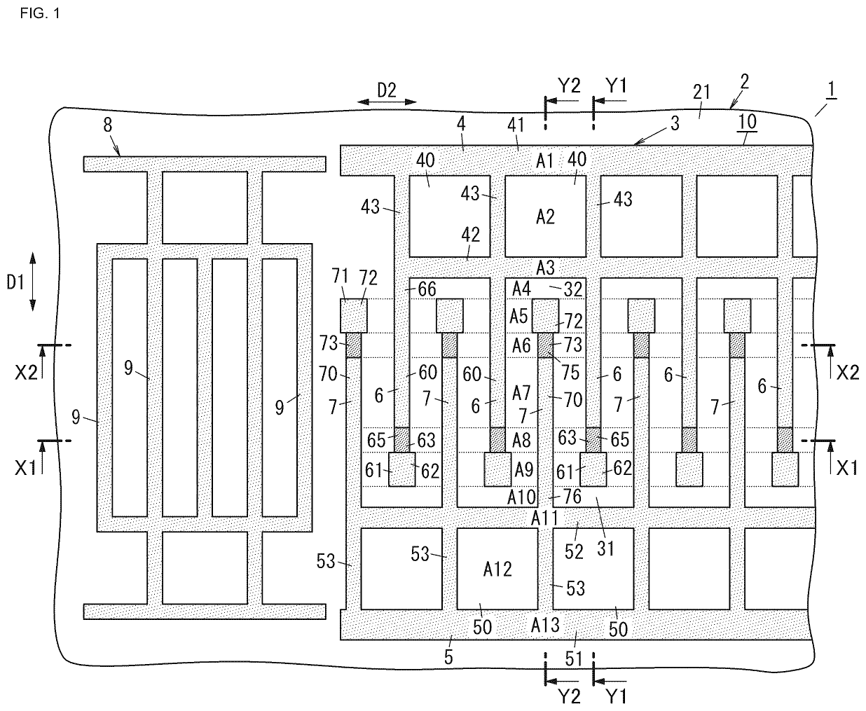

FIGS. 1 to 7, 8A, 8B, 11, and 12 referenced in first to third example embodiments and the like are schematic diagrams, and the ratios of the sizes and thicknesses of components in the diagrams are not necessarily identical to the actual ratios of dimensions.

### First Example Embodiment

### 1 Overview

As illustrated in FIG. 1, an acoustic wave device 1 according to a first example embodiment includes a piezoelectric substrate 2 and an IDT (interdigital transducer) electrode 3. The IDT electrode 3 is provided on the piezoelectric substrate 2. “The IDT electrode 3 is provided on the piezoelectric substrate 2” means that the IDT electrode 3 is provided directly or indirectly on the piezoelectric substrate 2. The acoustic wave device 1 further includes two reflectors 8 (only one reflector 8 is illustrated in FIG. 1) provided on the piezoelectric substrate 2. The acoustic wave device 1 according to the first example embodiment is a one-port acoustic wave resonator but is not limited to this. The IDT electrode 3 and the reflector 8 are dotted in FIG. 1, but the dotting does not represent cross sections and is provided to clarify the relationships between the IDT electrode 3, the reflector 8, and the piezoelectric substrate 2.

### 2 Details

The acoustic wave device 1 according to the first example embodiment will be described in more detail below with reference to FIGS. 1 to 7, 8A, and 8B.

### 2.1 Piezoelectric Substrate

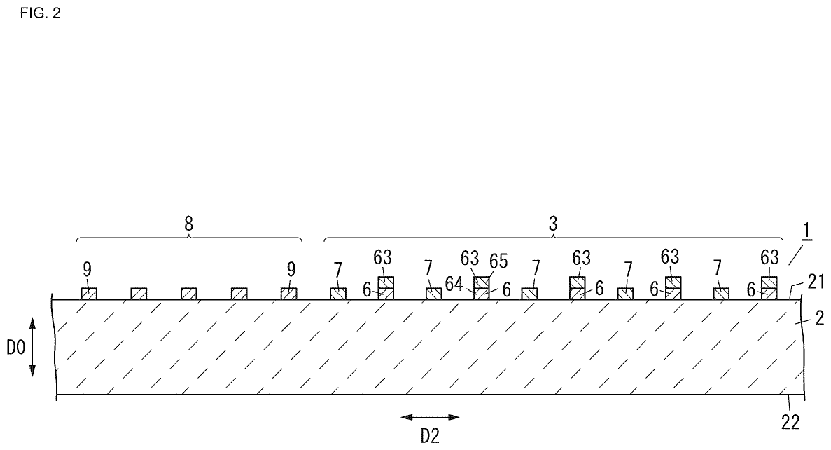

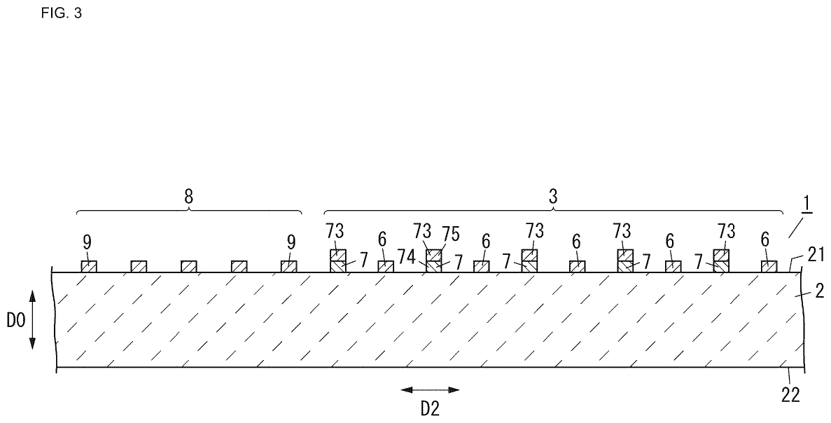

As illustrated in FIGS. 2 and 3, the piezoelectric substrate 2 includes a first main surface 21 and a second main surface 22 facing away from each other in a thickness direction DO of the piezoelectric substrate 2. Here, “facing away from each other” means facing away from each other geometrically instead of facing away from each other physically. In plan view in the thickness direction DO of the piezoelectric substrate 2, the outer edge of the piezoelectric substrate 2 has, for example, a rectangular or substantially rectangular shape.

The piezoelectric substrate 2 has piezoelectric properties. In the acoustic wave device 1 according to the first example embodiment, the piezoelectric substrate 2 is a single piezoelectric substrate. The material of the single piezoelectric substrate is, for example, lithium tantalate but is not limited to this, and the material may also be, for example, lithium niobate, zinc oxide, or aluminum nitride. When the single piezoelectric substrate is a lithium tantalate substrate, the lithium tantalate substrate is, for example, a 50° Y-cut X-propagation lithium tantalate substrate. When the single piezoelectric substrate is a Y-cut X-propagation lithium tantalate substrate, the acoustic wave device 1 can use, as a main mode, a mode in which an SH wave is a main component, by using a Love wave as an acoustic wave. It should be noted that the cut-angle and the single crystal material of the single piezoelectric substrate may be determined as appropriate in accordance with, for example, the required specifications (bandpass characteristics, attenuation characteristics, temperature characteristics, and filter characteristics such as band width) of the acoustic wave device 1. When the single piezoelectric substrate is a lithium niobate substrate, the lithium niobate substrate is, for example, a 128° Y-X lithium niobate substrate.

### 2.2 IDT Electrode

The IDT electrode 3 has electrical conductivity. The material of the IDT electrode 3 is, for example, aluminum, copper, platinum, gold, silver, titanium, nickel, chromium, molybdenum, tungsten, tantalum, magnesium, iron, or an alloy based on any of these metals. In addition, the IDT electrode 3 may have a structure in which a plurality of metal films made of these metals or alloys are laminated together.

As illustrated in FIG. 1, the IDT electrode 3 includes a first busbar 4, a second busbar 5, a plurality of first electrode fingers 6, and a plurality of second electrode fingers 7.

In the IDT electrode 3, the first busbar 4 and the second busbar 5 face each other in a first direction D1 perpendicular or substantially perpendicular the thickness direction D0 of the piezoelectric substrate 2. That is, the second busbar 5 faces the first busbar 4 in the first direction D1.

Each of the first busbar 4 and the second busbar 5 has an elongated shape with a longitudinal direction parallel to a second direction D2 perpendicular or substantially perpendicular the first direction D1. The second direction D2 is also perpendicular or substantially perpendicular the thickness direction D0 of the piezoelectric substrate 2.

The plurality of first electrode fingers 6 are connected to the first busbar 4 and extend from the first busbar 4 toward the second busbar 5 in the first direction D1. More specifically, the plurality of first electrode fingers 6 extend from the first busbar 4 in a direction perpendicular or substantially perpendicular the longitudinal direction of the first busbar 4. In the example in FIG. 1, the lengths of the plurality of first electrode fingers 6 are identical to each other. In the IDT electrode 3, the plurality of first electrode fingers 6 and the second busbar 5 are spaced apart from each other, and gaps 31 are provided between the first electrode fingers 6 and the second busbar 5 that face each other in the first direction D1. When the wavelength of the acoustic wave in the main mode described above is λ, a length L31 of the gaps 31 in the first direction D1 is, for example, about 0.5λ or less, for example.

The plurality of second electrode fingers 7 are connected to the second busbar 5 and extend from the second busbar 5 toward the first busbar 4 in the first direction D1. More specifically, the plurality of second electrode fingers 7 extend from the second busbar 5 in a direction perpendicular or substantially perpendicular the longitudinal direction of the second busbar 5. In the example in FIG. 1, the lengths of the plurality of second electrode fingers 7 are identical to each other. In the IDT electrode 3, the plurality of second electrode fingers 7 and the first busbar 4 are spaced apart from each other, and gaps 32 are provided between the second electrode fingers 7 and the first busbar 4 that face each other in the first direction D1. When the wavelength of the acoustic wave described above is λ, a length L32 of the gaps 32 in the first direction D1 is, for example, about 0.5λ or less, for example.

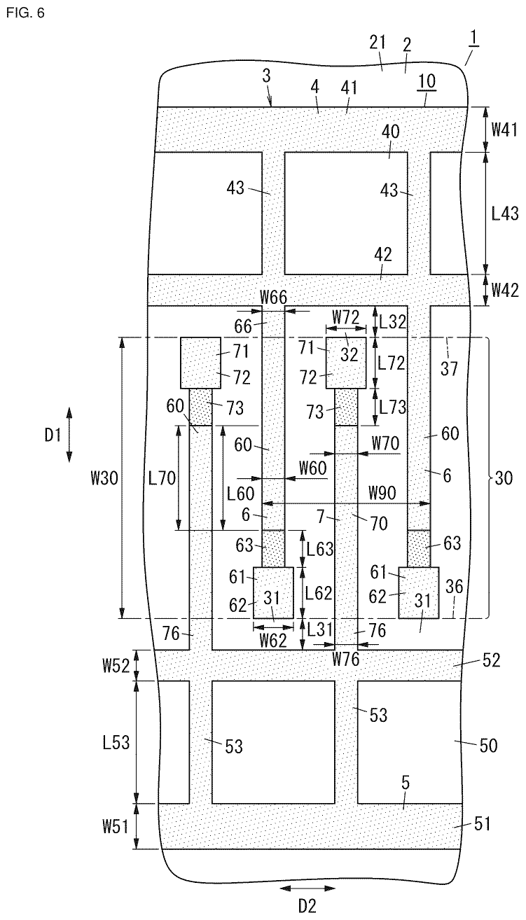

In the IDT electrode 3, the plurality of first electrode fingers 6 and the plurality of second electrode fingers 7 are alternately staggered in the second direction D2 perpendicular or substantially perpendicular the first direction D1 with a space therebetween. Accordingly, a first electrode finger 6 and a second electrode finger 7 adjacent to each other in the second direction D2 are spaced apart from each other. In the IDT electrode 3, the number of pairs of the first electrode finger 6 and the second electrode finger 7 is, for example, 100. That is, the IDT electrode 3 includes, for example, 100 of the first electrode fingers 6 and 100 of the second electrode fingers 7. The IDT electrode 3 excites the acoustic wave in an intersection region 30 (see FIG. 6). The intersection region 30 is a region between the envelope 36 of the front edges of the plurality of first electrode fingers 6 and the envelope 37 of the front edges of the plurality of second electrode fingers 7. The propagation direction of the acoustic wave is parallel or substantially parallel to the second direction D2. The characteristics of the resonator 10, which includes the IDT electrode 3 and a portion of the piezoelectric substrate 2, can be changed by changing, as appropriate, for example, the electrode finger pitch of the IDT electrode 3, a width W30 (also referred to below as the intersecting width W30) in the first direction D1 of the intersection region 30 of the IDT electrode 3, the material of the piezoelectric substrate 2, and the like. The electrode finger pitch of the IDT electrode 3 is defined by the distance between the center lines of two of the first electrode fingers 6 adjacent to each other of the plurality of first electrode fingers 6 or the distance between the center lines of two of the second electrode fingers 7 adjacent to each other of the plurality of second electrode fingers 7.

The first busbar, the second busbar, the plurality of first electrode fingers 6, and the plurality of second electrode fingers 7 will be described in more detail below.

The first busbar 4 includes a plurality of opening portions 40 (also referred to below as first opening portions 40), an inner busbar portion 42 (also referred to below as a first inner busbar portion 42), an outer busbar portion 41 (also referred to below as a first outer busbar portion 41), and a plurality of coupling portions 43 (also referred to below as first coupling portions 43). The plurality of first opening portions 40 are arranged at equal or substantially equal intervals in, for example, the second direction D2. The first inner busbar portion 42 is located closer than the plurality of first opening portions 40 to the plurality of first electrode fingers 6 and the plurality of second electrode fingers 7 in the first direction D1. The first outer busbar portion 41 is located opposite to the first inner busbar portion 42 across the plurality of first opening portions 40 in the first direction D1. That is, the first outer busbar portion 41 is located opposite to the plurality of first electrode fingers 6 in the first direction D1. The plurality of first coupling portions 43 connect the first inner busbar portion 42 and the first outer busbar portion 41 to each other in the first direction D1. The plurality of first coupling portions 43 are arranged at equal or substantially equal intervals in, for example, the second direction D2. One first opening portion 40 of the plurality of first opening portions 40 is located between two of the first coupling portions 43 adjacent to each other in the second direction D2 of the plurality of first coupling portions 43. That is, in the first busbar 4, the plurality of first coupling portions 43 and the plurality of first opening portions 40 are alternately arranged one by one in the second direction D2. The plurality of first coupling portions 43 correspond one-to-one to the plurality of first electrode fingers 6 and are aligned with the corresponding first electrode fingers 6 in the first direction D1 in the example in FIG. 1, but example embodiments of the present invention are not limited to this example. That is, the number of the first coupling portions 43 and the positions of the plurality of first coupling portions 43 are not limited to the example described above.

In addition, the opening shape of the plurality of first opening portions 40 is a rectangular or substantially rectangular, but the opening shape is not limited to this. When the wavelength of the acoustic wave described above is λ, a width W42 (see FIG. 6) of the first inner busbar portion 42 in the first direction D1 is, for example, about 0.5λ or less. In addition, a length L43 of the first coupling portion 43 in the first direction D1 is, for example, about 1.0λ or more.

The second busbar 5 includes a plurality of opening portions 50 (also referred to below as second opening portions 50), an inner busbar portion 52 (also referred to below as a second inner busbar portion 52), an outer busbar portion 51 (also referred to below as a second outer busbar portion 51), and a plurality of coupling portions 53 (also referred to below as second coupling portions 53). The plurality of second opening portions 50 are arranged at equal or substantially equal intervals in, for example, the second direction D2. The second inner busbar portion 52 is located closer than the plurality of second opening portions 50 to the plurality of first electrode fingers 6 and the plurality of second electrode fingers 7 in the first direction D1. The second outer busbar portion 51 is located opposite to the second inner busbar portion 52 across the plurality of second opening portions 50 in the first direction D1. That is, the second outer busbar portion 51 is located opposite to the plurality of second electrode fingers 7 in the first direction D1. The plurality of second coupling portions 53 couple the second inner busbar portion 52 and the second outer busbar portion 51 to each other in the first direction D1. The plurality of second coupling portions 53 are arranged at equal or substantially equal intervals in, for example, the second direction D2. One second opening portion 50 of the plurality of second opening portions 50 is located between two of the second coupling portions 53 adjacent to each other in the second direction D2 of the plurality of second coupling portions 53. That is, in the second busbar 5, the plurality of second coupling portions 53 and the plurality of second opening portions 50 are alternately arranged one by one in the second direction D2. The plurality of second coupling portions 53 correspond one-to-one to the plurality of second electrode fingers 7 and are aligned with the corresponding second electrode fingers 7 in the first direction D1 in the example in FIG. 1, but example embodiments of the present invention are not limited to this example. That is, the number of the second coupling portions 53 and the positions of the plurality of second coupling portions 53 are not limited to the example described above.

In addition, the opening shape of the plurality of second opening portions 50 is rectangular or substantially rectangular, but the opening shape is not limited to this. When the wavelength of the acoustic wave described above is λ, a width W52 (see FIG. 6) of the second inner busbar portion 52 in the first direction D1 is, for example, about 0.5λ or less. In addition, a length L53 of the second coupling portion 53 in the first direction D1 is, for example, about 1.0λ or more.

As illustrated in FIG. 1, each of the plurality of first electrode fingers 6 includes a base end portion 66 (also referred to below as a first base end portion 66), a middle portion 60 (also referred to below as a first middle portion 60), an intermediate portion 63 (also referred to below as a first intermediate portion 63), and a front-end portion 61 (also referred to below as a first front-end portion 61). In each of the plurality of first electrode fingers 6, the first base end portion 66, the first middle portion 60, the first intermediate portion 63, and the first front-end portion 61 are arranged in the first direction D1 in the order of the first base end portion 66, the first middle portion 60, the first intermediate portion 63, and the first front-end portion 61 from a first busbar 4 side. In addition, as illustrated in FIG. 1, each of the plurality of second electrode fingers 7 includes a base end portion 76 (also referred to below as a second base end portion 76), a middle portion 70 (also referred to below as a second middle portion 70), an intermediate portion 73 (also referred to below as a second intermediate portion 73), and a front-end portion 71 (also referred to below as a second front-end portion 71).

In each of the plurality of second electrode fingers 7, the second base end portion 76, the second middle portion 70, the second intermediate portion 73, and the second front-end portion 71 are arranged in the first direction D1 in the order the second base end portion 76, the second middle portion 70, the second intermediate portion 73, and the second front-end portion 71 from a second busbar 5 side.

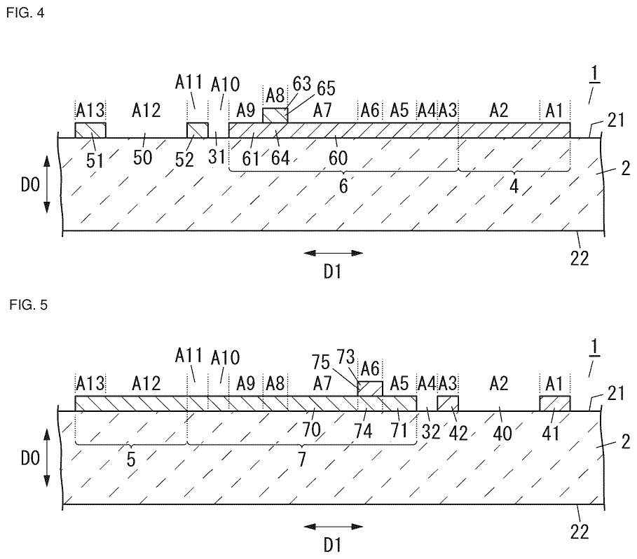

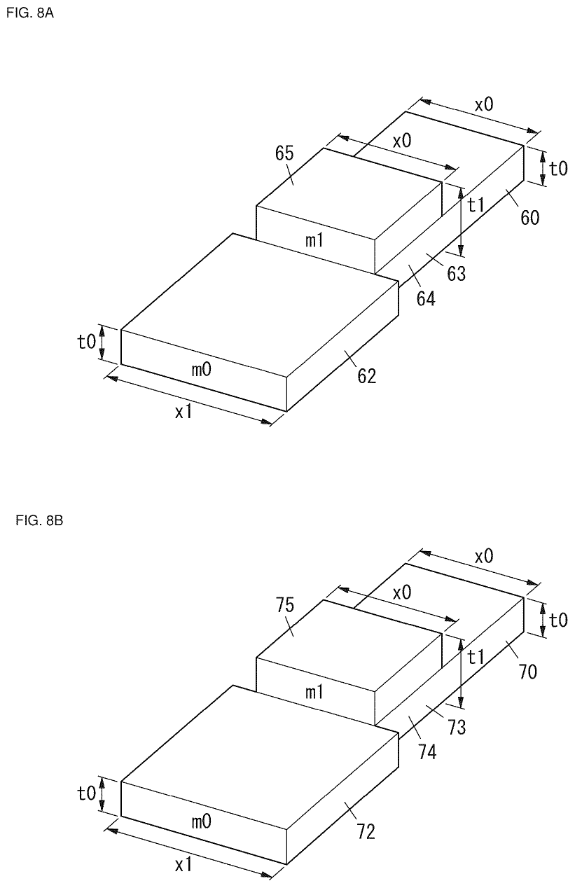

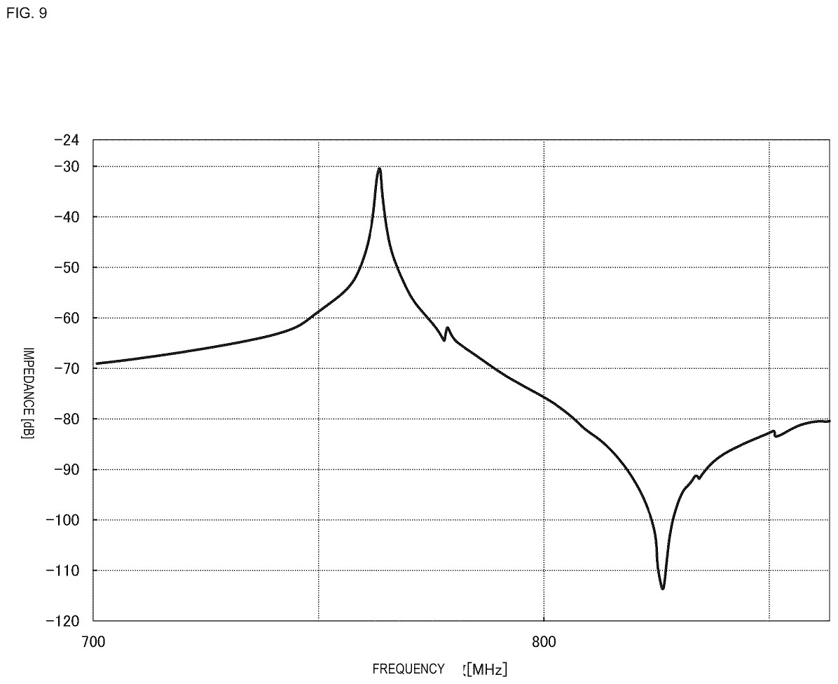

The first front-end portion 61 of each of the plurality of first electrode fingers 6 includes a wide portion 62 (also referred to below as a first wide portion 62). As illustrated in FIG. 6, a width W62 of a first wide portion 62 in the second direction D2 is greater than a width W60 of a first middle portion 60 in the second direction D2. As illustrated in FIGS. 2 and 4, the first intermediate portion 63 includes a base portion 64 provided on the piezoelectric substrate 2 and a mass-adding portion 65 provided on the base portion 64. The material of the base portion 64 is identical to the material of the first base end portion 66, the first middle portion 60, and the first front-end portion 61. In each of the plurality of first electrode fingers 6, the base portion 64, the first middle portion 60, and the first wide portion 62 have a first thickness to (see FIG. 8A). The material of the mass-adding portion 65 may be identical to or different from the material of the base portion 64. As illustrated in FIG. 1, the first middle portion 60 of the first electrode finger 6 is located between the first intermediate portion 63 of the first electrode finger 6 and a region of the second electrode finger 7 that overlaps the second intermediate portion 73 of the second electrode finger 7 in the second direction D2. The first base end portion 66 of the first electrode finger 6 is a portion between the first middle portion 60 and the first busbar 4 in the first direction D1. As illustrated in FIG. 6, a width W66 of the first base end portion 66 in the second direction D2 is identical to the width W60 of the first middle portion 60 in the second direction D2. In each of the plurality of first electrode fingers 6, a length L60 of the first middle portion 60 is greater than a length L62 of the first wide portion 62 and a length L63 of the first intermediate portion 63 in the first direction D1. The length L63 of the first wide portion 62 in the first direction D1 is preferably less than about 1.5λ. In each of the plurality of first electrode fingers 6, as illustrated in FIG. 8A, a second thickness t1 of the first intermediate portion 63 is greater than the first thickness to of the first wide portion 62 and the first middle portion 60.

In addition, in the example in FIG. 1, the first middle portions 60 of the plurality of first electrode fingers 6 have the same width W60. In addition, the first wide portions 62 of the first front-end portions 61 of the plurality of first electrode fingers 6 have the same width W62. Each of the plurality of first electrode fingers 6 is symmetrical with respect to the central line parallel to the first direction D1. The shape of the first wide portion 62 is rectangular or substantially rectangular but is not limited to this, and the shape may be, for example, a hexagon, a circle, or the like.

In the example in FIG. 1, the opening width of each of the plurality of first opening portions 40 in the second direction D2 is identical to, for example, the distance between the first middle portions 60 of two of the first electrode fingers 6 adjacent to each other in the second direction D2. The distance between the two of the first opening portions 40 adjacent to each other in the second direction D2 is identical to, for example, the width W60 of the first middle portion 60 of the first electrode finger 6.

The second front-end portion 71 of each of the plurality of second electrode fingers 7 includes a wide portion 72 (also referred to below as a second wide portion 72). As illustrated in FIG. 6, a width W72 of a second wide portion 72 in the second direction D2 is greater than a width W70 of a second middle portion 70 in the second direction D2. As illustrated in FIGS. 3 and 5, the second intermediate portion 73 includes a base portion 74 and a mass-adding portion 75 provided on the base portion 74. The material of the base portion 74 is identical to the material of the second base end portion 76, the second middle portion 70, and the second front-end portion 71. In each of the plurality of second electrode fingers 7, the base portion 74, the second middle portion 70, and the second wide portion 72 have the first thickness to (see FIG. 8B). The material of the mass-adding portion 75 may be identical to or different from the material of the base portion 74. The second middle portion 70 of the second electrode finger 7 is located between the second intermediate portion 73 of the second electrode finger 7 and a region of the second electrode finger 7 that overlaps the first intermediate portion 63 of the first electrode finger 6 in the second direction D2. The second base end portion 76 of the second electrode finger 7 is a portion between the second middle portion 70 and the second busbar 5 in the first direction D1. As illustrated in FIG. 6, a width W76 of the second base end portion 76 in the second direction D2 is identical to the width W70 of the second middle portion 70 in the second direction D2. In each of the plurality of second electrode fingers 7, a length L70 of the second middle portion 70 is greater than a length L72 of the second wide portion 72 and a length L73 of the second intermediate portion 73 in the first direction D1. The length L73 of the second wide portion 72 in the first direction D1 is preferably less than about 1.5λ. In each of the plurality of second electrode fingers 7, as illustrated in FIG. 8B, the second thickness t1 of the second intermediate portion 73 is greater than the first thickness to of the second wide portion 72 and the second middle portion 70.

In addition, in the example in FIG. 1, the second middle portions 70 of the plurality of second electrode fingers 7 have the same width W70. In addition, the second wide portions 72 of the second front-end portions 71 of the plurality of second electrode fingers 7 have the same width W72. Each of the plurality of second electrode fingers 7 is symmetrical with respect to the central line parallel to the first direction D1. The shape of the second wide portion 72 is rectangular or substantially rectangular but is not limited to this, and the shape may be, for example, a hexagon, a circle, or the like.

The opening width of each of the plurality of second opening portions 50 in the second direction D2 is identical to, for example, the distance between the second middle portions 70 of two second electrode fingers 7 adjacent to each other in the second direction D2. The distance between the two second opening portions 50 adjacent to each other in the second direction D2 is identical to, for example, the width W70 of the second middle portion 70 of the second electrode finger 7.

The acoustic wave device 1 according to the first example embodiment has a structure in which a transverse mode ripple is suppressed by generating a piston mode in the IDT electrode 3. This point will be described with reference to FIG. 5.

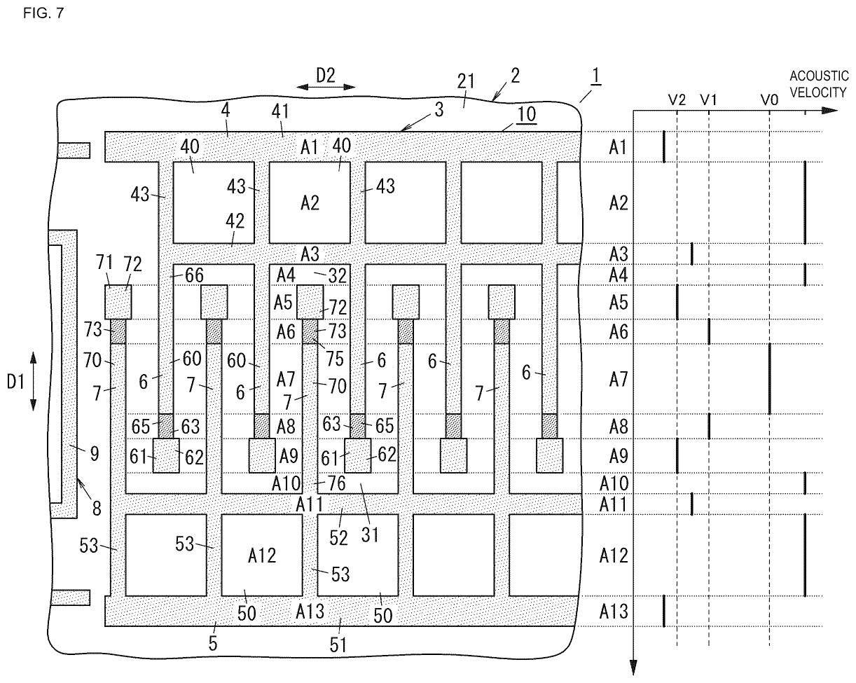

In the acoustic wave device 1, as illustrated in the left portion of FIG. 7, the resonator 10 including the IDT electrode 3 and a portion of the piezoelectric substrate 2 includes a plurality of (13) regions A1 to A13 arranged in the first direction D1 in plan view in the thickness direction D0 of the piezoelectric substrate 2. The 13 regions A1 to A13 include regions of the piezoelectric substrate 2 and the IDT electrode 3 that differ from each other. The velocities (acoustic velocities) of acoustic waves propagating through the 13 regions A1 to A11 are schematically illustrated in the right portion of FIG. 7.

In the resonator 10 of the acoustic wave device 1, the 13 regions A1 to A13 include a middle region A7 including the middle portion of the intersection region 30 of the IDT electrode 3 in the first direction D1. The middle region A7 includes the first middle portions 60 of the plurality of first electrode fingers 6 and the second middle portions 70 of the plurality of second electrode fingers 7. The middle region A7 is a region in which the first middle portions 60 of the plurality of first electrode fingers 6 and the second middle portions 70 of the plurality of second electrode fingers 7 overlap each other in the second direction D2. In the middle region A7, the value (duty ratio) obtained by dividing the electrode finger width (the width W60 of the first middle portion 60 of the first electrode finger 6 or the width W70 of the second middle portion 70 of the second electrode finger) by half the electrode finger pitch is, for example, about 0.5.

In the resonator 10 of the acoustic wave device 1, the 13 regions A1 to A13 include two regions A1 and A13 located at respective ends in the first direction D1. The region A1 (also referred to below as the first outer busbar region A1) includes the first outer busbar portion 41 of the first busbar 4. The region A13 (also referred to below as the second outer busbar region A13) includes the second outer busbar portion 51 of the second busbar 5. The acoustic wave velocity in the first outer busbar region A1 and the acoustic wave velocity in the second outer busbar region A13 are lower than the acoustic wave velocity in the middle region A7.

Of the 13 regions A1 to A13 in the resonator 10 of the acoustic wave device 1, two regions, A2 and A12, which are located second from respective ends in the first direction D1, are included. The region A2 (also referred to below as the first coupling region A2) includes the plurality of first coupling portions 43 and the plurality of first opening portions 40 of the first busbar 4. The region A12 (also referred to below as the second coupling region A12) includes the plurality of second coupling portions 53 and the plurality of second opening portions 50 of the second busbar 5. The acoustic wave velocity in the first coupling region A2 and the acoustic wave velocity in the second coupling region A12 are higher than the acoustic wave velocity in the first outer busbar region A1, the acoustic wave velocity in the second outer busbar region A13, and the acoustic wave velocity in the middle region A7.

Of the 13 regions A1 to A13 in the resonator 10 of the acoustic wave device 1, two regions, A3 and A11, which are located third from respective ends in the first direction D1, are included. The region A3 (also referred to below as the first inner busbar region A3) includes the first inner busbar portion 42 of the first busbar 4. The region A11 (also referred to below as the second inner busbar region A11) includes the second inner busbar portion 52 of the second busbar 5. The acoustic wave velocity in the first inner busbar region A3 and the acoustic wave velocity in the second inner busbar region A11 are lower than the acoustic wave velocity in the middle region A7.

Of the 13 regions A1 to A13 in the acoustic wave device 1, two regions, A4 and A10, which are located fourth from respective ends in the first direction D1, are included. The region A4 (also referred to below as the first gap region A4) includes the plurality of gaps 32 and portions of the plurality of first electrode fingers 6 that overlap the plurality of gaps 32 in the second direction D2. The region A10 (also referred to below as the second gap region A10) includes the plurality of gaps 31 and portions of the plurality of second electrode fingers 7 that overlap the plurality of gaps 31 in the second direction D2. The acoustic wave velocity in the first gap region A4 and the acoustic wave velocity in the second gap region A10 are higher than the acoustic wave velocity in the first inner busbar region A3, the acoustic wave velocity in the second inner busbar region A11, and the acoustic wave velocity in the middle region A7.

Of the 13 regions A1 to A13 in the resonator 10 of the acoustic wave device 1, the regions A5 and A9, which are located fifth from respective ends in the first direction D1, are included. The region A5 (also referred to below as the first edge region A5) includes the second wide portions 72 of the plurality of second electrode fingers 7 and portions of the plurality of f first electrode fingers 6 that overlap the second wide portions 72 in the second direction D2. The region A9 (also referred to below as the second edge region A9) includes the first wide portions 62 of the plurality of first electrode fingers 6 and portions of the plurality of second electrode fingers 7 that overlap the plurality of first wide portions 62 in the second direction D2. The acoustic wave velocity in the first edge region A5 and the acoustic wave velocity in the second edge region A9 are lower than the acoustic wave velocity in the middle region A7. In the resonator 10 of the acoustic wave device 1, the intersection region 30 has a first end close to the first busbar 4 and a second end close to the second busbar, and the first edge region A5 and the second edge region A9 correspond to the first end and the second edge, respectively, of the intersection region 30.

In the acoustic wave device 1, low acoustic velocity regions (the first edge region A5 and the first inner busbar region A3) in which the acoustic wave velocity is lower than in the middle region A7 are present on a first busbar 4 side of the middle region A7, and low acoustic velocity regions (the second edge region A9 and the second inner busbar region A11) in which the acoustic wave velocity is lower than in the middle region A7 are present on a second busbar 5 side of the middle region A7. In addition, in the resonator 10 of the acoustic wave device 1, high acoustic velocity regions (the first coupling region A2 and the second coupling region A12) in which the acoustic wave velocity is higher than in the middle region A7 are present on the outer side of the low acoustic velocity regions in the first direction D1. Accordingly, a piston mode can be generated in the acoustic wave device 1.

Of the 13 regions A1 to A13 in the resonator 10 of the acoustic wave device 1, the regions A6 and A8, which are located sixth from respective ends in the first direction D1, are included. The region A6 (also referred to below as the first intermediate region A6) includes the second intermediate portions 73 of the plurality of second electrode fingers 7 and portions of the plurality of first electrode fingers 6 that overlap the second intermediate portions 73 in the second direction D2. The region A8 (also referred to below as the second intermediate region A8) includes the first intermediate portions 63 of the plurality of first electrode fingers 6 and portions of the plurality of second electrode fingers 7 that overlap the first intermediate portions 63 in the second direction D2.

The acoustic wave velocity in the first intermediate region A6 and the acoustic wave velocity in the second intermediate region A8 are lower than the acoustic wave velocity in the middle region A7. In the resonator 10 of the acoustic wave device 1, when the acoustic wave velocity in the middle region A7 is V0, the acoustic wave velocity in the first intermediate region A6 and the second intermediate region A8 is V1, and the acoustic wave velocity in the first edge region A5 and the second edge region A9 are V2, V0>V1>V2 is satisfied.

As described above, the second thickness t1 of the first intermediate portion 63 and the second intermediate portion 73 is greater than the first thickness to of the first middle portion 60 and the second middle portion 70. To suppress a transverse mode ripple from occurring in the frequency characteristics of the resonator 10, the second thickness t1 of the first intermediate portion 63 and the second intermediate portion 73 is preferably less than twice the first thickness to of the first middle portion 60 and the second middle portion 70.

In the resonator 10 of the acoustic wave device 1, the following condition is satisfied: [Mass per unit length of a portion of the IDT electrode 3 that is present in the middle region A7]<[Mass per unit length of a portion of the IDT electrode 3 that is present in the first edge region A5 and the second edge region A9]<[Mass per unit length of a portion of the IDT electrode 3 that is present in the first intermediate region A6 and the second intermediate region A8]. This condition will be described with reference to FIGS. 8A and 8B. In FIG. 8A, the density of the first middle portion 60 having the first thickness to [m] and a first width x0 [m] is m0 [kg/m³]. In addition, in FIG. 8B, the density of the second middle portion 70 having the first thickness to [m] and the first width x0 [m] is m0 [kg/m³]. In FIG. 8A, in the first intermediate portion 63 having the second thickness t1 [m] and the first width x0 [m], the density of the base portion 64 is m0 [kg/m³], and the density of the mass-adding portion 65 is m1 [kg/m³]. In FIG. 8B, in the second intermediate portion 73 having the second thickness t1 [m] and the first width x0 [m], the density of the base portion 74 is m0 [kg/m³], and the density of the mass-adding portion 75 is m1 [kg/m³]. In addition, in FIG. 8A, the density of the first wide portion 62 having the first thickness t0 [m] and a second width x1 [m] is m0 [kg/m³]. In addition, in FIG. 8B, the density of the second wide portion 72 having the first thickness to [m] and the second width x1 [m] is m0 [kg/m³]. Further, each of the unit lengths is a length in the first direction D1 (intersecting width direction) and is 1. When the conditions described above are rewritten by using the parameters illustrated in FIGS. 8A and 8B, formula (1) is obtained.

### Math. 1

$$m 0 \cdot x 0 \cdot t 0 \cdot < \{ m 0 \cdot x 0 \cdot t 0 + m 1 \cdot x 0 \cdot ( t 1 - t 0 ) \} < m 0 \cdot x 1 \cdot t 0 \qquad Formula ( 1 )$$

When formula (1) is normalized by m0·x0·t0, formula (2) is obtained.

### Math. 2

$$1 < \{ 1 + \frac{m 1}{m 0} \cdot ( \frac{t 1}{t 0} - 1 ) \} < \frac{x 1}{x 0} \qquad Formula ( 2 )$$

In the resonator 10 of the acoustic wave device 1, when the condition of formula (2) is satisfied, the condition V0<V1<V2 (that is, V0>V1>V2) is satisfied.

In addition, the acoustic velocities of the regions A1 to A13 can be obtained by performing a finite element method simulation by using the parameters (such as the material, the Euler angle, and the thickness) of the piezoelectric substrate 2 and the parameters (such as the material, the thickness, and the electrode finger pitch) of IDT electrode 3.

### 2.3 Reflectors

The reflectors 8 are provided on the piezoelectric substrate 2. More specifically, the reflectors 8 are provided on the first main surface 21 of the piezoelectric substrate 2. The reflectors 8 are disposed on both sides in the second direction D2 of the IDT electrode 3 one for each.

Each of the reflectors 8 reflects an acoustic wave from the adjacent IDT electrode 3. Each of the reflectors 8 is a short-circuit grating. Each of the reflectors 8 has a plurality of electrode fingers 9. In the reflectors 8, the ends of the plurality of electrode fingers 9 in the first direction D1 are short-circuited together, and the other ends are short-circuited together. In FIG. 1, the number of the electrode fingers 9 of the reflector 8 is reduced to make the drawing easier to see. In addition, the length and the width of the electrode finger 9 differ from the actual length and width. The IDT electrode 3 is electrically conductive. The material of the IDT electrode 3 is, for example, aluminum, copper, platinum, gold, silver, titanium, nickel, chromium, molybdenum, tungsten, tantalum, magnesium, iron, or an alloy mainly including any of these metals. In addition, the IDT electrode 3 may have a structure in which a plurality of metal films made of these metals or alloys are laminated together. The thickness of each of the reflectors 8 is, for example, about 300 nm.

### 3 Characteristics of the Acoustic Wave Device

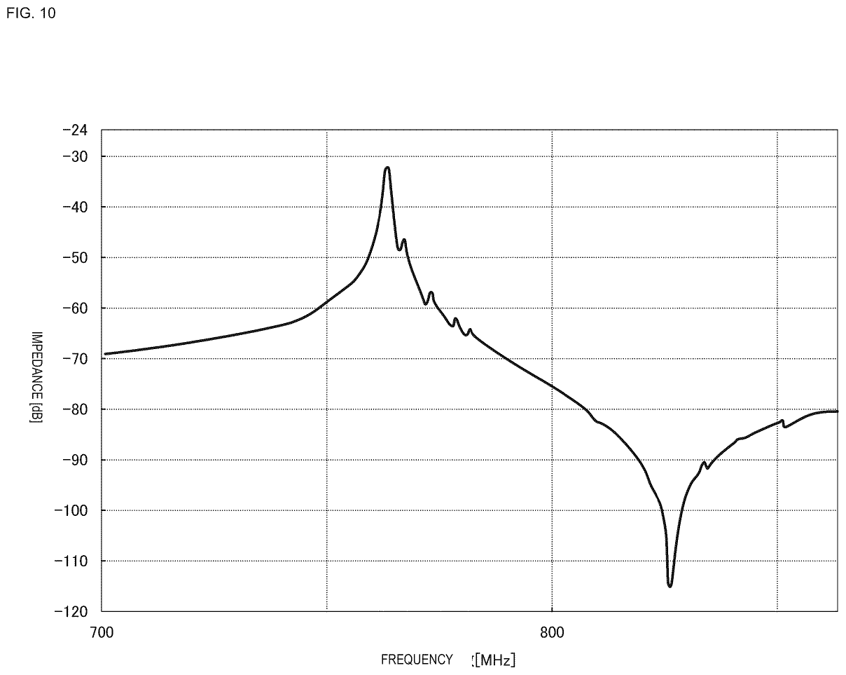

FIG. 9 illustrates impedance-frequency characteristics of the acoustic wave device 1 according to one example of the first example embodiment. In FIG. 9, the horizontal axis represents the frequency, and the vertical axis represents the impedance [dB] of the acoustic wave device 1. The impedance [dB] here is obtained by 20×log₁₀ |Z| where the impedance of the acoustic wave device 1 is Z. FIG. 10 illustrates impedance-frequency characteristics of an acoustic wave device according to a comparative example. The structural parameters of the one example described above are illustrated in Table 1 below. The wavelength λ of the acoustic wave is, for example, about 4.48 μm. In the one example described above, x1=1.41·x0, t1=1.33·t0, and m0<m1<1.2·m0. In addition, the comparative example described above differs from the one example described above in that the mass-adding portions 65 and 75 are not present in the one example.

TABLE 1

| | | Designed | |
|---|---|---|---|
| | Item | value | |
| IDT | Number of first electrode fingers 6 | 100 | |
| electrode 3 | Number of second electrode fingers 7 | 100 | |
| | First thickness t0 of middle | 300 | nm |
| | portions 60 and 70 | | |
| | First thickness t0 of wide portions 62 | 300 | nm |
| | and 72 | | |
| | Second thickness t1 of intermediate | 100 | nm |
| | portions 63 and 73 | | |
| Intersection | Intersecting width W30 | 31.4 | μm |
| region 30 | | | |
| Region A1 | Width W41 of outer busbar portion 41 | 3.00 | μm |
| Region A2 | Length of coupling portion 43 | 5.32 | μm |
| Region A3 | Width W42 of inner busbar portion 42 | 1.90 | μm |
| Region A4 | Length L32 of gap 32 | 0.62 | μm |
| Region A5 | Length L72 of wide portion 72 | 0.62 | μm |
| | Width W72 of wide portion 72 | 1.58 | μm |
| Region A6 | Length L73 of intermediate portion 73 | 0.50 | μm |
| Region A7 | Lengths of middle portions 60 and 70 | 29.16 | μm |
| Region A8 | Length L63 of intermediate portion 63 | 0.50 | μm |
| Region A9 | Length L62 of wide portion 62 | 0.62 | μm |
| | Width W62 of wide portion 62 | 1.58 | μm |
| Region A10 | Length L31 of gap 31 | 0.62 | μm |
| Region A11 | Width W52 of inner busbar portion 52 | 1.90 | μm |
| Region A12 | Length of coupling portion 53 | 5.32 | μm |
| Region A13 | Width W51 of outer busbar portion 51 | 3.00 | μm |

In accordance with the results in FIGS. 9 and 10, the acoustic wave device 1 according to the first example embodiment can suppress the ripple (transverse mode ripple) of an unwanted wave that occurs between a resonance point and an anti-resonance point in impedance characteristics unlike the acoustic wave device according to the comparative example.

### 4 Effects

In the acoustic wave device 1 according to the first example embodiment, the resonator 10 that includes the IDT electrode 3 and a portion of the piezoelectric substrate 2 includes the regions A1 to A13, and the regions A1 to A13 include the middle region A7, the first edge region A5, the second edge region A9, the first intermediate region A6, and the second intermediate region A8. In the acoustic wave device 1 according to the first example embodiment, the acoustic wave velocity in the first intermediate region A6 and the acoustic wave velocity in the second intermediate region A8 are lower than the acoustic wave velocity in the middle region A7 and higher than the acoustic wave velocity in the first edge region A5 and the acoustic wave velocity in the second edge region A9. As a result, the acoustic wave device 1 according to the first example embodiment can suppress the ripple of an unwanted wave. More specifically, in the acoustic wave device 1 according to the first example embodiment, the number of regions having different acoustic velocities is larger, the mode distribution (mode distribution caused by the transverse mode) of an unwanted wave is suppressed in the front-end portions 71 of the second electrode fingers 7, and the ripple of an unwanted wave that occurs between a resonance point and an antiresonance point is suppressed as compared with the case in which the first intermediate region A6 and the second intermediate region A8 are not present. As a result, the acoustic wave device 1 according to the first example embodiment suppresses the ripple of an unwanted wave that occurs in a pass zone.

In addition, in the second edge region A9 of the acoustic wave device 1 according to the first example embodiment, each of the first front-end portions 61 of the plurality of first electrode fingers 6 includes the first wide portion 62. In each of the plurality of first electrode fingers 6, the width W62 of the first wide portion 62 in the second direction D2 is greater than the width of the middle portion 60 in the second direction D2. As a result, in the acoustic wave device 1 according to the first example embodiment, the acoustic velocity V2 in the second edge region A9 can be lower than the acoustic velocity V1 in the middle region A7. In addition, in the first edge region A5 of the acoustic wave device 1 according to the first example embodiment, the second front-end portion 71 of each of the plurality of second electrode fingers 7 includes the second wide portion 72. In each of the plurality of second electrode fingers 7, the width W72 of the second wide portion 72 in the second direction D2 is greater than the width W70 of the middle portion 70 in the second direction D2. As a result, in the acoustic wave device 1 according to the first example embodiment, the acoustic velocity V2 in the first edge region A5 can be lower than the acoustic velocity V1 in the middle region A7.

In addition, in the acoustic wave device 1 according to the first example embodiment, the resonator 10 including the IDT electrode 3 and a portion of the piezoelectric substrate 2 includes the regions A1 to A13, and the regions A1 to A13 include the middle region A7, the first edge region A5, the second edge region A9, the first intermediate region A6, and the second intermediate region A8. In the acoustic wave device 1 according to the first example embodiment, the first intermediate region A6 is located between the middle region A7 and the first edge region A5. The second intermediate region A8 is located between the middle region A7 and the second edge region A9. Each of the plurality of second electrode fingers 7 has the first thickness to and the first width x0 in the middle region A7, has the first thickness to and the second width x1 in the first edge region A5, and has the second thickness t1 and the first width x0 in the first intermediate region A6. In addition, each of the plurality of first electrode fingers 6 has the first thickness to and the first width x0 in the middle region A7, has the second thickness t1 and the first width x0 in the second edge region A9, and has the second thickness t1 and the first width x0 in the second intermediate region A8. The second thickness t1 is greater than the first thickness to, and the second width x1 is greater than the first width x0. As a result, the acoustic wave device 1 according to the first example embodiment can suppress the ripple of an unwanted wave. More specifically, in the acoustic wave device 1 according to the first example embodiment, the number of regions having different acoustic velocities increases, the mode distribution (mode distribution caused by the transverse mode) of an unwanted wave is suppressed in the front-end portions 71 of the second electrode fingers 7, and the ripple of an unwanted wave that occurs between a resonance point and an antiresonance point is suppressed as compared with the case in which the first intermediate region A6 and the second intermediate region A8 are not present. As a result, the acoustic wave device 1 according to the first example embodiment suppresses the ripple of an unwanted wave that occurs in a pass zone. Here, in the acoustic wave device 1 according to the first example embodiment, the acoustic wave velocity in the first intermediate region A6 and the acoustic wave velocity in the second intermediate region A8 are lower than the acoustic wave velocity in the middle region A7 and higher than the acoustic wave velocity in the first edge region A5 and the acoustic wave velocity in the second edge region A9. As a result, the acoustic wave device 1 according to the first example embodiment can further suppress the ripple of an unwanted wave.

### Second Example Embodiment

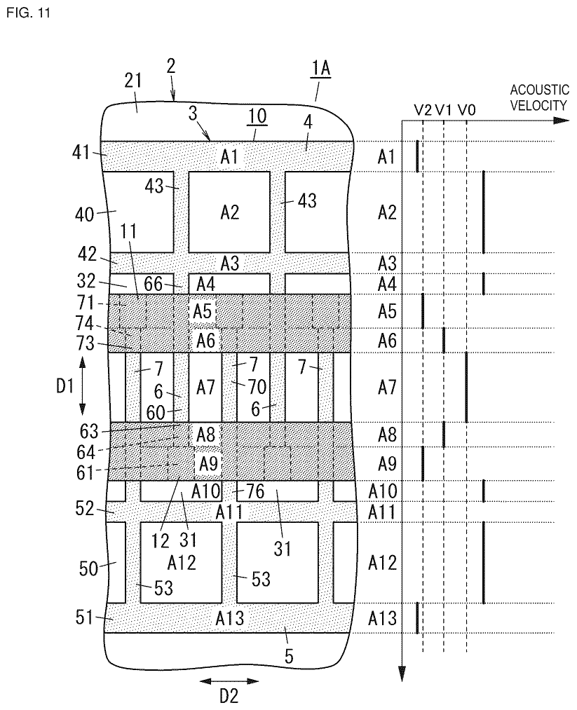

An acoustic wave device 1A according to a second example embodiment will be described with reference to FIG. 11. In the acoustic wave device 1A according to the second example embodiment, components that are identical to those in the acoustic wave device 1 according to the first example embodiment (see FIG. 1) are given the same reference numerals, and the description thereof will be omitted.

### 1 Structure

The acoustic wave device 1A according to the second example embodiment includes a first mass-adding film 11 instead of including the wide portion 72 and the mass-adding portion 75 of each of the second electrode fingers 7 of the acoustic wave device 1 according to the first example embodiment. The first mass-adding film 11 covers a portion of the first main surface 21 of the piezoelectric substrate 2, the front-end portions 71 of the plurality of second electrode fingers 7, and the base portions 74 of the plurality of second electrode fingers 7. The first mass-adding film 11 is a dielectric film. The material of the first mass-adding film 11 includes, for example, silicon oxide.

The acoustic wave device 1A according to the second example embodiment includes a second mass-adding film 12 instead of having the wide portion 62 and the mass-adding portion 65 of each of the first electrode fingers 6 of the acoustic wave device 1 according to the first example embodiment. The second mass-adding film 12 covers a portion of the first main surface 21 of the piezoelectric substrate 2, the front-end portions 61 of the plurality of first electrode fingers 6, and the base portions 64 of the plurality of first electrode fingers 6. The second mass-adding film 12 is a dielectric film. The material of the second mass-adding film 12 includes, for example, silicon oxide.

In addition, in the acoustic wave device 1A, the first edge region A5 includes at least a portion of the first mass-adding film 11 that overlaps the front-end portions 71 of the plurality of second electrode fingers 7. The second edge region A9 includes at least a portion of the second mass-adding film 12 that overlaps the front-end portions 61 of the plurality of first electrode fingers 6.

### 2 Effects

In the acoustic wave device 1A according to the second example embodiment, since the first edge region A5 includes at least a portion of the first mass-adding film 11, the acoustic velocity V2 in the first edge region A5 can be lower than the acoustic velocity V1 in the middle region A7. In addition, in the acoustic wave device 1A according to the second example embodiment, since the second edge region A9 includes at least a portion of the second mass-adding film 12, the acoustic velocity V2 in the second edge region A9 can be lower than the acoustic velocity V1 in the middle region A7. As a result, the acoustic wave device 1A according to the second example embodiment can suppress the ripple of an unwanted wave.

### Third Example Embodiment

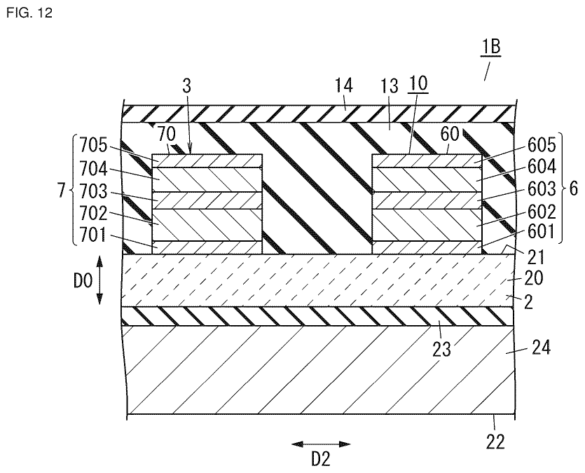

An acoustic wave device 1B according to a third example embodiment will be described with reference to FIG. 12. In the acoustic wave device 1B according to the third example embodiment, components that are identical to those in the acoustic wave device 1 according to the first example embodiment (see FIG. 1) are given the same reference numerals, and the description thereof will be omitted.

### 1 Structure

In the acoustic wave device 1B, the piezoelectric substrate 2 includes a piezoelectric layer 20 and a support substrate 24 that is joined to the piezoelectric layer 20. The support substrate 24 is joined to the piezoelectric layer 20 via the dielectric film 23, but example embodiments of the present invention is not limited to this example, and the support substrate 24 may be directly joined to the piezoelectric layer 20 without the dielectric film 23. The piezoelectric layer 20 has piezoelectric properties. The material of the piezoelectric layer 20 is identical to the material of the single piezoelectric substrate described in the first example embodiment. The material of the dielectric film 23 is, for example, silicon oxide but is not limited to this, and the material may be silicon nitride. In addition, the material of the dielectric film 23 may be a compound obtained by adding fluorine, carbon, or boron to silicon oxide. The support substrate 24 supports the piezoelectric layer 20.

The linear expansion coefficient of the support substrate 24 is smaller than the linear expansion coefficient of the piezoelectric layer 20. The outer edge of the support substrate 24 has a rectangular or substantially rectangular shape in plan view in the thickness direction D0 of the piezoelectric substrate 2. The size of the support substrate 24 is identical to the size of the piezoelectric layer 20 in plan view in the thickness direction D0 of the piezoelectric substrate 2. The support substrate 24 is a silicon substrate. The thickness of the silicon substrate is preferably, for example, about 10λ or more and about 180 μm or less. The resistivity of the silicon substrate is, for example, about 1 kΩcm or more, preferably about 2 kΩcm or more, and more preferably about 4 kΩcm or more. The thickness of the support substrate 24 is, for example, about 120 μm. The support substrate 24 is not limited to a silicon substrate and may be, for example, a silicon nitride substrate, a sapphire substrate, or a spinel substrate.

In addition, the acoustic wave device 1B according to the third example embodiment further includes a first protective film 13 that covers the IDT electrode 3 and the reflectors 8 on the piezoelectric substrate 2 and a second protective film 14 that covers the first protective film 13. The material of the first protective film 13 is, for example, silicon oxide. The material of the second protective film 14 is, for example, silicon nitride. It should be noted that the acoustic wave device 1B need not include the second protective film 14. In addition, in the acoustic wave device 1B, the surface shapes of the first protective film 13 and the second protective film 14 are flat but is not limited to this, and the shapes may have irregularities corresponding to the shape of the IDT electrode 3.

The shape of the IDT electrode 3 of the acoustic wave device 1B according to the third example embodiment is identical to the shape of the IDT electrode 3 of the acoustic wave device 1 according to the first example embodiment (see FIG. 1). Accordingly, in the resonator 10 of the acoustic wave device 1B according to the third example embodiment, V0>V1>V2 is satisfied as in the resonator 10 of the acoustic wave device 1.

### 2 Effects

The acoustic wave device 1B according to the third example embodiment can suppress the ripple of an unwanted wave as the acoustic wave device 1 according to the first example embodiment. In addition, since the piezoelectric substrate 2 of the acoustic wave device 1B according to the third example embodiment includes the piezoelectric layer 20 and the support substrate 24 joined to the piezoelectric layer 20, favorable main mode characteristics are obtained and the level of a ripple caused by the transverse mode is relatively low. As a result, the acoustic wave device 1B according to the third example embodiment can suppress the ripple of an unwanted wave that occurs between a resonance point and an anti-resonance point.

In addition, since the acoustic wave device 1B according to the third example embodiment has the support substrate 24 joined to the piezoelectric layer 20, the temperature characteristics are improved and the temperature dependence of a transverse mode ripple is improved.

In addition, since the piezoelectric layer 20 is supported by the support substrate 24 in the acoustic wave device 1B, the thickness of the piezoelectric layer 20 may be smaller than the thickness of the single piezoelectric substrate constituting the piezoelectric substrate 2 the acoustic wave device 1. In the acoustic wave device 1B, the Q value can be improved by setting the thickness of the piezoelectric layer 20 to about 3.5λ or less. In this case, in the support substrate 24, the acoustic velocity of a bulk wave propagating through the piezoelectric layer 20 is higher than the acoustic velocity of an acoustic wave propagating through the piezoelectric layer 20. Here, the bulk wave propagating through the support substrate 24 has the lowest acoustic velocity of the plurality of bulk waves propagating through the support substrate 24. In addition, in the acoustic wave device 1B, the dielectric film 23 can also serve as a low-acoustic velocity film. The acoustic velocity of a bulk wave propagating through the low-acoustic velocity film is lower than the acoustic velocity of a bulk wave propagating through the piezoelectric layer 20. The thickness of the low-acoustic velocity film is preferably about 2.0λ or less, for example. In the acoustic wave device 1B, the film stress can be reduced by setting the thickness of the low-acoustic velocity film to about 2.0λ or less, for example, and accordingly, the warpage of a wafer used for the support substrate 24 can be reduced when the acoustic wave device 1B is manufactured, the rate of non-defective products can be improved, and the characteristics can be stabilized.

The first to third example embodiments are only examples of the various example embodiment of the present invention. The example embodiments described above and the like can be variously changed depending on the design or the like as long as an object of the present invention can be achieved.

For example, in the acoustic wave devices 1 and 1B, at least one first electrode finger 6 of the plurality of first electrode fingers 6 need only have the wide portion 62 and the intermediate portion 63, and not all of the first electrode fingers 6 need have the wide portion 62 and the intermediate portion 63. In addition, in the acoustic wave devices 1 and 1B, at least one second electrode finger 7 of the plurality of second electrode fingers 7 need only have the wide portion 72 and the intermediate portion 73, and not all of the second electrode fingers 7 need not have the wide portion 72 and the intermediate portion 73.

In addition, in the acoustic wave devices 1 and 1B, the shapes of the mass-adding portions 65 and 75 in plan view in the thickness direction D0 of the piezoelectric substrate 2 are not limited to rectangular and may be circular. In this case, the mass-adding portions 65 and 75 are cylindrical. In addition, in plan view in the thickness direction D0 of the piezoelectric substrate 2, the diameters of the mass-adding portions 65 and 75 are less than or equal to, for example, the widths W60 and W70 of the middle portions 60 and 70.

In addition, in the acoustic wave devices 1 and 1B, the wide portion 62 included in the front-end portion 61 of first electrode finger 6 may be formed in at least a portion of the front-end portion 61 of the first electrode finger 6 in the longitudinal direction of first electrode finger 6. The wide portion 72 included in the front-end portion 71 of the second electrode finger 7 may be provided in at least a portion of the front-end portion 71 of the second electrode finger 7 in the longitudinal direction of the second electrode finger 7.

In addition, in the acoustic wave devices 1, 1A, and 1B, the plurality of first electrode fingers 6 and the plurality of second electrode fingers 7 need only be arranged apart from each other in the second direction D2 in the IDT electrode 3, and the plurality of first electrode fingers 6 and the plurality of second electrode fingers 7 need not be alternately arranged apart from each other. For example, in the IDT electrode 3, a region in which one first electrode finger 6 and one second electrode finger 7 are spaced apart from each other may be mixed with a region in which two first electrode fingers 6 or two second electrode fingers 7 are arranged in the second direction D2.

In addition, the IDT electrode 3 is a regular-type IDT electrode but is not limited to this, and the IDT electrode 3 may be, for example, an inclined-type IDT electrode. Accordingly, the second direction D2 need only intersect the first direction D1.

In addition, the inner busbar portion 42 may include a slit through which the opening portion 40 communicates with the gap 32. That is, the inner busbar portion 42 may be discontinuous in the second direction D2. In addition, the inner busbar portion 52 may have a slit through which the opening portion 50 communicates with the gap 31. That is, the inner busbar portion 52 may be discontinuous in the second direction D2.

In addition, in the acoustic wave devices 1, 1A, and 1B, the reflector 8 is not limited to a short-circuit grating and may be, for example, an open grating, a positive-negative reflective grating, or the like. In addition, in the acoustic wave devices 1, 1A, and 1B, the reflector 8 is not an essential component.

In addition, in the acoustic wave devices 1, 1A, and 1B, the resonator 10 may be a longitudinally coupled resonator.

In addition, the IDT electrode 3 is provided directly on the piezoelectric substrate 2 in the acoustic wave devices 1, 1A, and 1B but is not limited to this, and the IDT electrode 3 may be provided indirectly on the piezoelectric substrate 2. For example, in the acoustic wave devices 1, 1A, and 1B, the IDT electrode 3 may be provided on the piezoelectric substrate 2 via a dielectric film.

In addition, one IDT electrode 3 is provided on the piezoelectric substrate 2 in the acoustic wave devices 1, 1A, and 1B, but the number of IDT electrodes 3 is not limited to one and may be two or more. That is, each of the acoustic wave devices 1, 1A, and 1B may include a plurality of IDT electrodes 3. In this case, each of the acoustic wave devices 1, 1A, and 1B may be, for example, a ladder-type filter each having a plurality of resonators 10 each including a plurality of IDT electrodes 3.

In addition, in the acoustic wave devices 1 and 1A, the piezoelectric substrate 2 may include the piezoelectric layer 20 and the support substrate 24 joined to the piezoelectric layer 20 as in the acoustic wave device 1B.

### Aspects

The specification discloses aspects described below.

An acoustic wave device (1, 1A, 1B) according to a first aspect includes a piezoelectric substrate (2) and an IDT electrode (3). The IDT electrode (3) is provided on the piezoelectric substrate (2). The IDT electrode (3) includes a first busbar (4), a second busbar (5), a plurality of first electrode fingers (6), and a plurality of second electrode fingers (7). The second busbar (5) faces the first busbar (4) in a first direction (D1). The plurality of first electrode fingers (6) are connected to the first busbar (4) and extend from the first busbar (4) toward the second busbar (5) in the first direction (D1). The plurality of second electrode fingers (7) are connected to the second busbar (5) and extend from the second busbar (5) toward the first busbar (4) in the first direction (D1). In the IDT electrode (3), the plurality of first electrode fingers (6) and the plurality of second electrode fingers (7) are spaced apart from each other in a second direction (D2) intersecting the first direction (D1). The first busbar (4) and the second busbar (5) include opening portions (40) and (50), inner busbar portions (42) and (52), outer busbar portions (41) and (51), and coupling portions (43) and (53), respectively. The inner busbar portions (42) and (52) are located closer than the opening portions (40) and (50) to the plurality of first electrode fingers (6) and the plurality of second electrode fingers (7), respectively, in the first direction (D1). The outer busbar portions (41) and (51) are located opposite to the inner busbar portions (42) and (52) across the opening portions (40) and (50), respectively, in the first direction (D1). The coupling portions (43) and (53) couple the inner busbar portions (42) and (52) and the outer busbar portions (41) and (51), respectively, to each other in the first direction (D1). When a region between an envelope (36) of front edges of the plurality of first electrode fingers (6) and an envelope (37) of front edges of the plurality of second electrode fingers (7) is an intersection region (30), a resonator (10) including the IDT electrode (3) and a portion of the piezoelectric substrate (2) includes a plurality of regions (A1) to (A13) that differ from each other in the first direction (D1) in plan view in a thickness direction (D0) of the piezoelectric substrate (2). The plurality of regions (A1) to (A13) include a middle region (A7), a first gap region (A4), a second gap region (A10), a first edge region (A5), a second edge region (A9), a first intermediate region (A6), and a second intermediate region (A8). The middle region (A7) includes a middle portion in the first direction (D1) of the intersection region (30) of the IDT electrode (3), middle portions (60) in the first direction (D1) of the plurality of first electrode fingers (6), and middle portions (70) in the first direction (D1) of the plurality of second electrode fingers (7). The first gap region (A4) includes gaps (32) between the first busbar (4) and the plurality of second electrode fingers (7). The second gap region (A10) includes gaps (31) between the second busbar (5) and the plurality of first electrode fingers (6). The first edge region (A5) includes front-end portions (71) of the plurality of second electrode fingers (7). The second edge region (A9) includes front-end portions (61) of the plurality of first electrode fingers (6). The first intermediate region (A6) is located between the middle region (A7) and the first edge region (A5). The second intermediate region (A8) is located between the middle region (A7) and the second edge region (A9). An acoustic wave velocity in the first gap region (A4) and an acoustic wave velocity in the second gap region (A10) are higher than an acoustic wave velocity in the middle region (A7). An acoustic wave velocity in the first intermediate region (A6) and an acoustic wave velocity in the second intermediate region (A8) are lower than the acoustic wave velocity in the middle region (A7) and higher than an acoustic wave velocity in the first edge region (A5) and an acoustic wave velocity in the second edge region (A9).

According to this aspect, the ripple of an unwanted wave can be further suppressed.

In an acoustic wave device (1, 1A, 1B) according to a second aspect, the front-end portion (61) of at least one first electrode finger (6) of the plurality of first electrode fingers (6) includes a first wide portion (62) in the second edge region (A9) in the first aspect. A width (W62) of the first wide portion (62) in the second direction (D2) is greater than a width (W60) of the middle portion (60) of the at least one first electrode finger (6) in the second direction (D2). In the first edge region (A5), the front-end portion (71) of at least one second electrode finger (7) of the plurality of second electrode fingers (7) includes a second wide portion (72). A width (W72) of the second wide portion (72) in the second direction (D2) is greater than a width (W70) of the middle portion (70) of the at least one second electrode finger (7) in the second direction (D2).

According to this aspect, since the front-end portion (61) of at least one first electrode finger (6) of the plurality of first electrode fingers (6) includes the first wide portion (62), an acoustic velocity (V2) in the second edge region (A9) can be lower than an acoustic velocity (V1) in the middle region (A7). In addition, according to this aspect, since the front-end portion (71) of at least one second electrode finger (7) of the plurality of second electrode fingers (7) includes the second wide portion (72), the acoustic velocity (V2) in the first edge region (A5) can be lower than the acoustic velocity (V1) in the middle region (A7).

In an acoustic wave device (1A) according to a third aspect, the first edge region (A5) includes at least a portion of a first mass-adding film (11) that overlaps a front-end portion (71) of at least one second electrode finger (7) of the plurality of second electrode fingers (7) in the first aspect. The second edge region (A9) includes at least a portion of the second mass-adding film (12) that overlaps the front-end portion (61) of at least one first electrode finger (6) of the plurality of first electrode fingers (6).

According to this aspect, since the first edge region (A5) includes at least a portion of the first mass-adding film (11), the acoustic velocity (V2) in the first edge region (A5) can be lower than the acoustic velocity (V1) in the middle region (A7). In addition, according to this aspect, since the second edge region (A9) includes at least a portion of the second mass-adding film (12), the acoustic velocity (V2) in the second edge region (A9) can be lower than the acoustic velocity (V1) in the middle region (A7).

An acoustic wave device (1, 1B) according to a fourth aspect includes a piezoelectric substrate (2) and an IDT electrode (3). The IDT electrode (3) is provided on the piezoelectric substrate (2). The IDT electrode (3) includes a first busbar (4), a second busbar (5), a plurality of first electrode fingers (6), and a plurality of second electrode fingers (7). The second busbar (5) faces the first busbar (4) in a first direction (D1). The plurality of first electrode fingers (6) are connected to the first busbar (4) and extend from the first busbar (4) toward the second busbar (5) in the first direction (D1). The plurality of second electrode fingers (7) are connected to the second busbar (5) and extend from the second busbar (5) toward the first busbar (4) in the first direction (D1). In the IDT electrode (3), the plurality of first electrode fingers (6) and the plurality of second electrode fingers (7) are spaced apart from each other in a second direction (D2) intersecting the first direction (D1). The first busbar (4) and the second busbar (5) include opening portions (40) and (50), inner busbar portions (42) and (52), outer busbar portions (41) and (51), and coupling portions (43) and (53), respectively. The inner busbar portions (42) and (52) are located closer than the opening portions (40) and (50) to the plurality of first electrode fingers (6) and the plurality of second electrode fingers (7), respectively, in the first direction (D1). The outer busbar portions (41) and (51) are located opposite to the inner busbar portions (42) and (52) across the opening portions (40) and (50), respectively, in the first direction (D1). The coupling portions (43) and (53) couple the inner busbar portions (42) and (52) and the outer busbar portions (41) and (51), respectively, to each other in the first direction (D1). When a region between an envelope (36) of front edges of the plurality of first electrode fingers (6) and an envelope (37) of front edges of the plurality of second electrode fingers (7) is an intersection region (30), a resonator (10) including the IDT electrode (3) and a portion of the piezoelectric substrate (2) includes a plurality of regions (A1) to (A13) that differ from each other in the first direction (D1) in plan view in a thickness direction (D0) of the piezoelectric substrate (2). The plurality of regions (A1) to (A13) include a middle region (A7), a first gap region (A4), a second gap region (A10), a first edge region (A5), a second edge region (A9), a first intermediate region (A6), and a second intermediate region (A8). The middle region (A7) includes a middle portion in the first direction (D1) of the intersection region (30) of the IDT electrode (3), middle portions (60) in the first direction (D1) of the plurality of first electrode fingers (6), and middle portions (70) in the first direction (D1) of the plurality of second electrode fingers (7). The first gap region (A4) includes gaps (31) between the first busbar (4) and the plurality of second electrode fingers (7). The second gap region (A10) includes gaps (32) between the second busbar (5) and the plurality of first electrode fingers (6). The first edge region (A5) includes front-end portions (71) of the plurality of second electrode fingers (7). The second edge region (A9) includes front-end portions (61) of the plurality of first electrode fingers (6). The first intermediate region (A6) is located between the middle region (A7) and the first edge region (A5). The second intermediate region (A8) is located between the middle region (A7) and the second edge region (A9). At least one second electrode finger (7) of the plurality of second electrode fingers (7) has a first thickness (t0) and a first width (x0) in the middle region (A7), has the first thickness (t0) and a second width (x1) in the first edge region (A5), and has a second thickness (t1) and the first width (x0) in the first intermediate region (A6). At least one first electrode finger (6) of the plurality of first electrode fingers (6) has the first thickness (t0) and the first width (x0) in the middle region (A7), has the second thickness (t1) and the first width (x0) in the second edge region (A9), and has the second thickness (t1) and the first width (x0) in the second intermediate region (A8). The second thickness (t1) is greater than the first thickness (t0), and the second width (x1) is greater than the first width (x0).

According to this aspect, the ripple of an unwanted wave can be further suppressed.

An acoustic wave device (1, 1B) according to a fifth aspect is based on the fourth aspect. An acoustic wave velocity in the first intermediate region (A6) and an acoustic wave velocity in the second intermediate region (A8) are lower than an acoustic wave velocity in the middle region (A7) and are higher than an acoustic wave velocity in the first edge region (A5) and an acoustic wave velocity in the second edge region (A9).

According to this aspect, the ripple of an unwanted wave can be further suppressed.

In an acoustic wave device (1, 1A, 1B) according to a sixth aspect, the piezoelectric substrate (2) includes the piezoelectric layer (20) and the support substrate (24) joined to the piezoelectric layer (20) in any one of the first to fifth aspects.

According aspect, favorable main mode to this characteristics are obtained, and the level of a ripple caused by the transverse mode becomes relatively low.

In an acoustic wave device (1, 1A, 1B) according to a seventh aspect, the second direction (D2) is perpendicular or substantially perpendicular the first direction (D1) in any one of the first to sixth aspects.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate; and
an IDT electrode on the piezoelectric substrate; wherein
the IDT electrode includes a first busbar, a second busbar that faces the first busbar in a first direction, a plurality of first electrode fingers that are connected to the first busbar and extend from the first busbar toward the second busbar in the first direction, and a plurality of second electrode fingers that are connected to the second busbar and extend from the second busbar toward the first busbar in the first direction;
in the IDT electrode, the plurality of first electrode fingers and the plurality of second electrode fingers are spaced apart from each other in a second direction intersecting the first direction;
each of the first busbar and the second busbar includes an opening portion, an inner busbar portion located closer than the opening portion to the plurality of first electrode fingers and the plurality of second electrode fingers in the first direction, an outer busbar portion located opposite to the inner busbar portion across the opening portion in the first direction, and a coupling portion that couples the inner busbar portion and the outer busbar portion to each other in the first direction;
when a region between an envelope of front edges of the plurality of first electrode fingers and an envelope of front edges of the plurality of second electrode fingers is an intersection region, a resonator including the IDT electrode and a portion of the piezoelectric substrate includes a plurality of regions that differ from each other in the first direction in plan view in a thickness direction of the piezoelectric substrate; and
the plurality of regions include a middle region that includes a middle portion in the first direction of the intersection region of the IDT electrode, middle portions in the first direction of the plurality of first electrode fingers, and middle portions in the first direction of the plurality of second electrode fingers, a first gap region including gaps between the first busbar and the plurality of second electrode fingers, a second gap region including gaps between the second busbar and the plurality of first electrode fingers, a first edge region including front-end portions of the plurality of second electrode fingers, a second edge region including front-end portions of the plurality of first electrode fingers, a first intermediate region located between the middle region and the first edge region, and a second intermediate region located between the middle region and the second edge region;
an acoustic wave velocity in the first gap region and an acoustic wave velocity in the second gap region are higher than an acoustic wave velocity in the middle region; and
an acoustic wave velocity in the first intermediate region and an acoustic wave velocity in the second intermediate region are lower than the acoustic wave velocity in the middle region and higher than an acoustic wave velocity in the first edge region and an acoustic wave velocity in the second edge region.

2. The acoustic wave device according to claim 1, wherein
in the second edge region, the front-end portion of at least one first electrode finger of the plurality of first electrode fingers includes a first wide portion, and a width of the first wide portion in the second direction is greater than a width of the middle portion of the at least one first electrode finger of the first electrode fingers in the second direction; and
in the first edge region, the front-end portion of at least one second electrode finger of the plurality of second electrode fingers includes a second wide portion, and a width of the second wide portion in the second direction is greater than a width of the middle portion of the at least one second electrode finger of the second electrode fingers in the second direction.

3. The acoustic wave device according to claim 1, wherein
the first edge region includes at least a portion of a first mass-adding film that overlaps the front-end portion of at least one second electrode finger of the plurality of second electrode fingers; and
the second edge region includes at least a portion of a second mass-adding film that overlaps the front-end portion of at least one first electrode finger of the plurality of first electrode fingers.

4. The acoustic wave device according to claim 1, wherein the piezoelectric substrate further includes a piezoelectric layer and a support substrate joined to the piezoelectric layer.

5. The acoustic wave device according to claim 1, wherein the second direction is perpendicular or substantially perpendicular to the first direction.

6. The acoustic wave device according to claim 1, further comprising reflectors at ends of the IDT electrode.

7. The acoustic wave device according to claim 1, wherein the acoustic wave device is a one-port acoustic wave resonator.

8. The acoustic wave device according to claim 1, wherein the acoustic wave device is structured to generate an SH wave or a Love wave.

9. The acoustic wave device according to claim 1, wherein the acoustic wave device is structured to generate a piston mode in the IDT electrode.

10. The acoustic wave device according to claim 1, wherein acoustic wave device is structured to suppress a ripple of a wave generated between a resonance point and an anti-resonance point.

11. An acoustic wave device comprising:
a piezoelectric substrate; and
an IDT electrode on the piezoelectric substrate; wherein
the IDT electrode includes a first busbar, a second busbar that faces the first busbar in a first direction, a plurality of first electrode fingers that are connected to the first busbar and extend from the first busbar toward the second busbar in the first direction, and a plurality of second electrode fingers that are connected to the second busbar and extend from the second busbar toward the first busbar in the first direction;
in the IDT electrode, the plurality of first electrode fingers and the plurality of second electrode fingers are spaced apart from each other in a second direction intersecting the first direction;
each of the first busbar and the second busbar includes an opening portion, an inner busbar portion located closer than the opening portion to the plurality of first electrode fingers and the plurality of second electrode fingers in the first direction, an outer busbar portion located opposite to the inner busbar portion across the opening portion in the first direction, and a coupling portion that couples the inner busbar portion and the outer busbar portion to each other in the first direction;
when a region between an envelope of front edges of the plurality of first electrode fingers and an envelope of front edges of the plurality of second electrode fingers is an intersection region, a resonator including the IDT electrode and a portion of the piezoelectric substrate includes a plurality of regions that differ from each other in the first direction in plan view in a thickness direction of the piezoelectric substrate; and
the plurality of regions include a middle region that includes a middle portion in the first direction of the intersection region of the IDT electrode, middle portions in the first direction of the plurality of first electrode fingers, and middle portions in the first direction of the plurality of second electrode fingers, a first gap region including gaps between the first busbar and the plurality of second electrode fingers, a second gap region including gaps between the second busbar and the plurality of first electrode fingers, a first edge region including front-end portions of the plurality of second electrode fingers, a second edge region including front-end portions of the plurality of first electrode fingers, a first intermediate region located between the middle region and the first edge region, and a second intermediate region located between the middle region and the second edge region;
at least one second electrode finger of the plurality of second electrode fingers has a first thickness and a first width in the middle region, has the first thickness and a second width in the first edge region, and has a second thickness and the first width in the first intermediate region;
at least one first electrode finger of the plurality of first electrode fingers has the first thickness and the first width in the middle region, has the second thickness and the first width in the second edge region, and has the second thickness and the first width in the second intermediate region; and
the second thickness is greater than the first thickness, and the second width is greater than the first width.

12. The acoustic wave device according to claim 11, wherein an acoustic wave velocity in the first intermediate region and an acoustic wave velocity in the second intermediate region are lower than an acoustic wave velocity in the middle region and higher than an acoustic wave velocity in the first edge region and an acoustic wave velocity in the second edge region.

13. The acoustic wave device according to claim 11, wherein the piezoelectric substrate further includes a piezoelectric layer and a support substrate joined to the piezoelectric layer.

14. The acoustic wave device according to claim 11, wherein the second direction is perpendicular or substantially perpendicular to the first direction.

15. The acoustic wave device according to claim 11, further comprising reflectors at ends of the IDT electrode.

16. The acoustic wave device according to claim 11, wherein the acoustic wave device is a one-port acoustic wave resonator.

17. The acoustic wave device according to claim 11, wherein the acoustic wave device is structured to generate an SH wave or a Love wave.

18. The acoustic wave device according to claim 11, wherein the acoustic wave device is structured to generate a piston mode in the IDT electrode.

19. The acoustic wave device according to claim 11, wherein acoustic wave device is structured to suppress a ripple of a wave generated between a resonance point and an anti-resonance point.
